(19) United States
(12) Patent Application Publication
(10) Pub. No.: US 2023/0238418 A1
(43) Pub. Date: Jul. 27, 2023

(54) IMAGE SENSING DEVICE

(71) Applicant: SK hynix Inc., Icheon-si (KR)

(72) Inventors: Jin Hee CHO, Icheon-si (KR); Young Jun KWON, Icheon-si (KR)

(21) Appl. No.: 17/973,046

(22) Filed: Oct. 25, 2022

(30) Foreign Application Priority Data
Jan. 21, 2022 (KR) 10-2022-0009282

(51) Int. Cl. H01L 27/146

(52) U.S. Cl. CPC H01L 27/14689; H01L 27/1461; H01L 27/14614; H01L 27/14643

(57) ABSTRACT

A method for manufacturing an image sensing device includes forming a first photoelectric conversion region in a semiconductor substrate, forming a recess region to extend in a direction from a surface of the semiconductor substrate toward an inside of the semiconductor substrate, arranging a mask in a portion of the recess region, forming a second photoelectric conversion region through the recess region, and forming a recess gate in the recess region. A thickness of the second photoelectric conversion region is based on a depth of the recess gate that is measured from the surface of the semiconductor substrate to a bottom surface of the recess gate.

### CROSS-REFERENCE TO RELATED APPLICATION

This patent document claims the priority and benefits of Korean patent application No. 10-2022-0009282, filed on Jan. 21, 2022, the disclosure of which is incorporated by reference in its entirety as part of the disclosure of this patent document.

### TECHNICAL FIELD

The technology and implementations disclosed in this patent document generally relate to an image sensing device.

### BACKGROUND

An image sensing device is a device for capturing optical images by converting light into electrical signals using a photosensitive semiconductor material which reacts to light. With the development of automotive, medical, computer and communication industries, the demand for high-performance image sensing devices is increasing in various fields such as smart phones, digital cameras, game machines, IoT (Internet of Things), robots, security cameras and medical micro cameras.

The image sensing device may be roughly divided into CCD (Charge Coupled Device) image sensing devices and CMOS (Complementary Metal Oxide Semiconductor) image sensing devices. The CCD image sensing devices offer a better image quality, but they tend to consume more power and are larger as compared to the CMOS image sensing devices.

The CMOS image sensing devices are smaller in size and consume less power than the CCD image sensing devices. Furthermore, CMOS sensors are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology provide an image sensing device with improved photocharge transfer efficiency and reduced noise.

In accordance with an embodiment of the disclosed technology, a method for manufacturing an image sensing device includes forming a first photoelectric conversion region in a semiconductor substrate; forming a recess region to extend in a direction from a surface of the semiconductor substrate to an inside of the semiconductor substrate; arranging a mask in a portion of the recess region; forming a second photoelectric conversion region through the recess region; and forming a recess gate in the recess region. A thickness of the second photoelectric conversion region is based on a depth of the recess gate that is measured from the surface of the semiconductor substrate to a bottom surface of the recess gate.

In some implementations, the second photoelectric conversion region may be in contact with a surface of the first photoelectric conversion region.

In some implementations, the forming the recess gate may include forming a gate insulation layer in the recess gate; and forming a gate electrode at an upper portion of the gate insulation layer.

In some implementations, the second photoelectric conversion region may be doped with impurities having a conductivity type as same as that of the first photoelectric conversion region.

In some implementations, the second photoelectric conversion region may be spaced apart from the recess gate.

In some implementations, the arranging the mask may include selectively masking the recess region except for a region in which the second photoelectric conversion region is to be formed.

In some implementations, the arranging the mask may include arranging the mask at a side surface of the recess region such that the mask is not disposed at a bottom surface of the recess region.

In some implementations, the forming the second photoelectric conversion region may include implanting impurities through the bottom surface of the recess region that is not masked.

In accordance with another embodiment of the disclosed technology, an image sensing device is provided to include a pixel array of a plurality of unit pixels configured to produce electronic charge in response to incident light for imaging sensing. Each of the plurality of unit pixels includes a first photoelectric conversion region disposed in a semiconductor substrate, a recess gate extending in a direction from a surface of the semiconductor substrate to an inside of the semiconductor substrate, and a second photoelectric conversion region disposed between the recess gate and the first photoelectric conversion region. In a first unit pixel and a second unit pixel that are included in the pixel array, a depth of the recess gate included in the first unit pixel and measured from the surface of the semiconductor substrate to a bottom surface of the recess gate in the first unit pixel may be greater than a depth of the recess gate included in the second unit pixel and measured from the surface of the semiconductor substrate to a bottom surface of the recess gate in the second unit pixel, a thickness of a second photoelectric conversion region included in the first unit pixel may be smaller than a thickness of a second photoelectric conversion region included in the second unit pixel.

In some implementations, in each of the plurality of unit pixels, the second photoelectric conversion region may be in contact with a surface of the first photoelectric conversion region.

In some implementations, in each of the plurality of unit pixels, the second photoelectric conversion region may be spaced apart from the recess gate.

In some implementations, in each of the plurality of unit pixels, the second photoelectric conversion region may be doped with impurities having a conductivity type as same as that of the first photoelectric conversion region.

In some implementations, the recess gate may further include a gate electrode, and a gate insulation layer disposed between the gate electrode and the second photoelectric conversion region.

In some implementations, a first distance between the bottom surface of the recess gate and the second photoelectric conversion region of the first unit pixel is equal to a second distance between the bottom surface of the recess gate and the second photoelectric conversion region of the second unit pixel.

In some implementations, a sum of the depth of the recess gate of the first unit pixel and the thickness of the second photoelectric conversion region of the first unit pixel is equal to a sum of the depth of the recess gate of the second unit pixel and the thickness of the second photoelectric conversion region of the second unit pixel.

In some implementations, the first photelectric conversion regions of the first unit pixel and the second unit pixel include a first surface closer to the surface of the semiconductor substrate and a second surface opposite to the first surface.

In some implementations, the thickness of the second photoelectric conversion region of each of the first unit pixel and the second unit pixel depends on a concentration of impurities, a strength of impurity implantation, or a number of times of impurity implantations.

In some implementations, the recess gate corresponds to a transfer transistor gate included in a transfer transistor.

In some implementations, the first unit pixel and the second unit pixel further comprises floating diffusion regions disposed to contact the recess gates of the first unit pixel and the second unit pixel.

In some implementations, in each of the first unit pixel and the second unit pixel, a length of a channel region formed between the floating diffusion region and the second photoelectric conversion region depend on a distance between the floating diffusion region and the second photoelectric conversion region.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a cross-sectional view illustrating an example of unit pixels disposed in a pixel array based on some implementations of the disclosed technology.

FIGS. 3A to 3H are cross-sectional views illustrating a method for forming a unit pixel based on some implementations of the disclosed technology.

FIG. 4 is a circuit diagram illustrating an equivalent circuit of a unit pixel based on some implementations of the disclosed technology.

### DETAILED DESCRIPTION

This patent document provides implementations and examples of image sensing device designs that may be used in configurations to substantially address one or more technical or engineering issues and to mitigate limitations or disadvantages encountered in some other image sensing device designs. Some implementations of the disclosed technology relate to an image sensing device with improved photocharge transfer efficiency and reduced noise. The disclosed technology provides the image sensing device which allows a second photoelectric conversion region to be disposed between a recess gate and a first photoelectric conversion region, so that transfer efficiency of photocharges generated in the first photoelectric conversion region can increase by the second photoelectric conversion region.

Hereafter, various embodiments will be described with reference to the accompanying drawings. These embodiments of the disclosed technology may provide a variety of effects capable of being directly or indirectly recognized through the disclosed technology. It should be understood that the disclosed technology is not limited to specific embodiments or the use of specific features in these specific embodiments, but can be implemented in various configurations based on the disclosed embodiments and modifications, equivalents and/or alternatives of the disclosed embodiments or other embodiments.

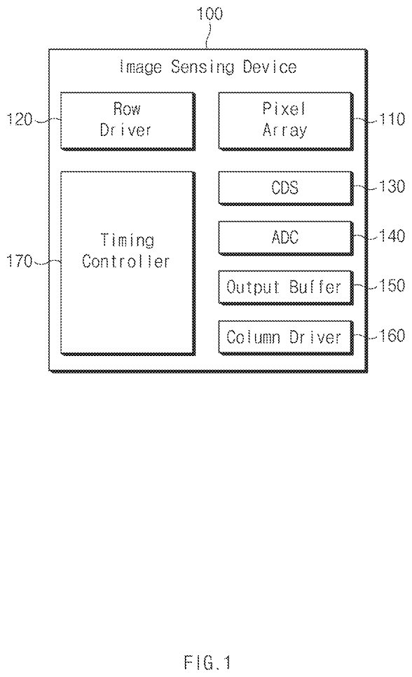

FIG. 1 is a block diagram illustrating an image sensing device 100 based on some implementations of the disclosed technology.

Referring to FIG. 1, the image sensing device 100 may include a pixel array 110, a row driver 120, a correlated double sampler (CDS) 130, an analog-digital converter (ADC) 140, an output buffer 150, a column driver 160, and a timing controller 170. The components of the image sensing device 100 illustrated in FIG. 1 are discussed by way of example only, and this patent document encompasses numerous other changes, substitutions, variations, alterations, and modifications.

The pixel array 110 may include a plurality of unit imaging pixels arranged in rows and columns. Each unit imaging pixel includes at least one photoelectric conversion region that responds to incident light and converts light into electric charge for imaging sensing. In one example, the plurality of unit imaging pixels can be arranged in a two-dimensional pixel array including rows and columns. In another example, the plurality of unit imaging pixels can be arranged in a three-dimensional pixel array. The plurality of unit pixels may convert an optical signal into an electrical signal on a unit pixel basis or a pixel group basis, where unit pixels in a pixel group share at least certain internal circuitry.

The pixel group may include any number of unit pixels. For example, the unit pixels included in the pixel group may be arranged in a matrix array. The pixel array 110 may receive driving signals, including a row selection signal, a pixel reset signal and a transfer signal, from the row driver 120. Upon receiving the driving signal, corresponding imaging pixels in the pixel array 110 may be activated to perform the operations corresponding to the row selection signal, the pixel reset signal, and the transfer signal.

The row driver 120 may activate the pixel array 110 to perform certain operations on the imaging pixels in the corresponding row based on commands and control signals provided by controller circuitry such as the timing controller 170. In some implementations, the row driver 120 may select one or more imaging pixels arranged in one or more rows of the pixel array 110. The row driver 120 may generate a row selection signal to select one or more rows among the plurality of rows. The row driver 120 may sequentially enable the pixel reset signal for resetting imaging pixels corresponding to at least one selected row, and the transfer signal for the pixels corresponding to the at least one selected row. Thus, a reference signal and an image signal, which are analog signals generated by each of the imaging pixels of the selected row, may be sequentially transferred to the CDS 130. The reference signal may be an electrical signal that is provided to the CDS 130 when a sensing node of an imaging pixel (e.g., a floating diffusion region node) is reset, and the image signal may be an electrical signal that is provided to the CDS 130 when photocharges generated by the imaging pixel are accumulated in the sensing node. The reference signal indicating unique reset noise of each pixel and the image signal indicating the intensity of incident light may be collectively referred to as a pixel signal as necessary.

CMOS image sensors may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some embodiments of the disclosed technology, the CDS 130 may sequentially sample and hold voltage levels of the reference signal and the image signal, which are provided to each of a plurality of column lines from the pixel array 110. That is, the CDS 130 may sample and hold the voltage levels of the reference signal and the image signal which correspond to each of the columns of the pixel array 110.

In some implementations, the CDS 130 may transfer the reference signal and the image signal of each of the columns as a correlate double sampling signal to the ADC 140 based on control signals from the timing controller 170.

The ADC 140 is used to convert analog CDS signals into digital signals. In some implementations, the ADC 140 may be implemented as a ramp-compare type ADC. The ramp-compare type ADC may include a comparator circuit for comparing the analog pixel signal with a reference signal such as a ramp signal that ramps up or down, and a timer counts until a voltage of the ramp signal matches the analog pixel signal. In some embodiments of the disclosed technology, the ADC 140 may convert the correlate double sampling signal generated by the CDS 130 for each of the columns into a digital signal, and output the digital signal. The ADC 140 may perform a counting operation and a computing operation based on the correlate double sampling signal for each of the columns and a ramp signal provided from the timing controller 170. In this way, the ADC 140 may eliminate or reduce noises such as reset noise arising from the imaging pixels when generating digital image data.

The ADC 140 may include a plurality of column counters. Each column of the pixel array 110 is coupled to a column counter, and image data can be generated by converting the correlate double sampling signals received from each column into digital signals using the column counter. In another embodiment of the disclosed technology, the ADC 140 may include a global counter to convert the correlate double sampling signals corresponding to the columns into digital signals using a global code provided from the global counter.

The output buffer 150 may temporarily hold the column-based image data provided from the ADC 140 to output the image data. In one example, the image data provided to the output buffer 150 from the ADC 140 may be temporarily stored in the output buffer 150 based on control signals of the timing controller 170. The output buffer 150 may provide an interface to compensate for data rate differences or transfer rate differences between the image sensing device 100 and other devices.

The column driver 160 may select a column of the output buffer upon receiving a control signal from the timing controller 170, and sequentially output the image data, which are temporarily stored in the selected column of the output buffer 150. In some implementations, upon receiving an address signal from the timing controller 170, the column driver 160 may generate a column selection signal based on the address signal and select a column of the output buffer 150, outputting the image data as an output signal from the selected column of the output buffer 150.

The timing controller 170 may control operations of the row driver 120, the ADC 140, the output buffer 150 and the column driver 160.

The timing controller 170 may provide the row driver 120, the column driver 160 and the output buffer 150 with a clock signal required for the operations of the respective components of the image sensing device 100, a control signal for timing control, and address signals for selecting a row or column. In an embodiment of the disclosed technology, the timing controller 170 may include a logic control circuit, a phase lock loop (PLL) circuit, a timing control circuit, a communication interface circuit and others.

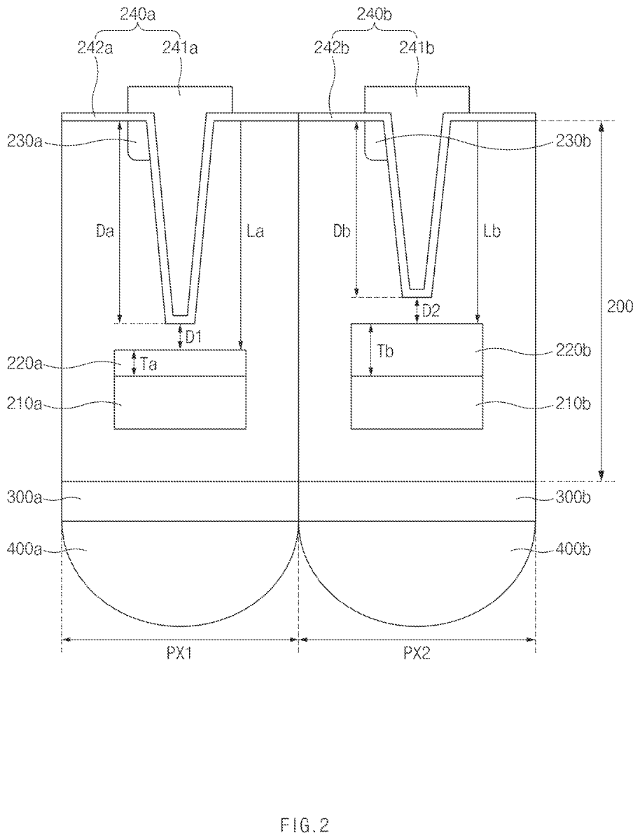

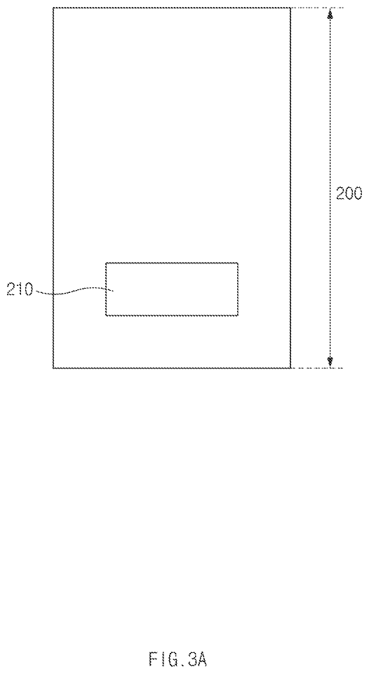

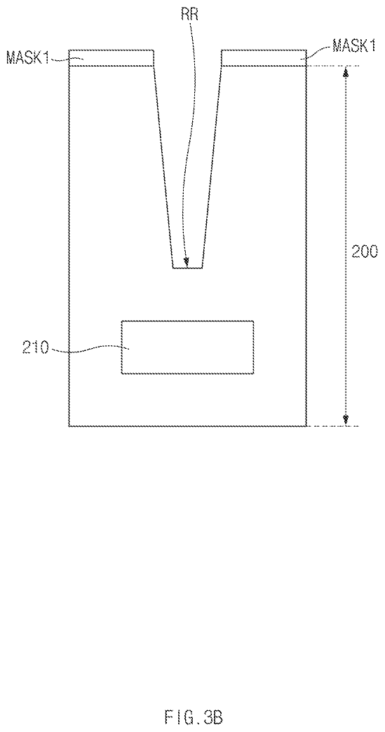

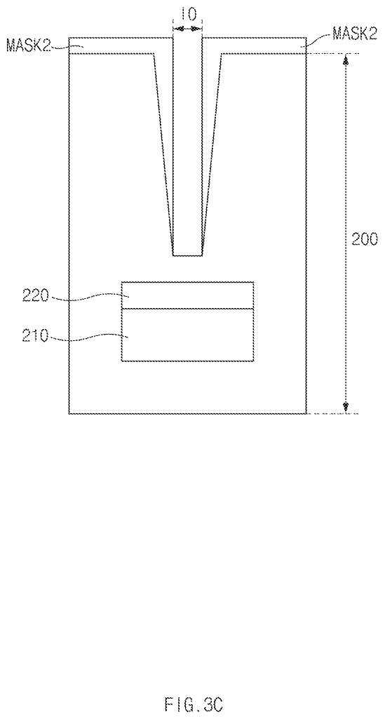

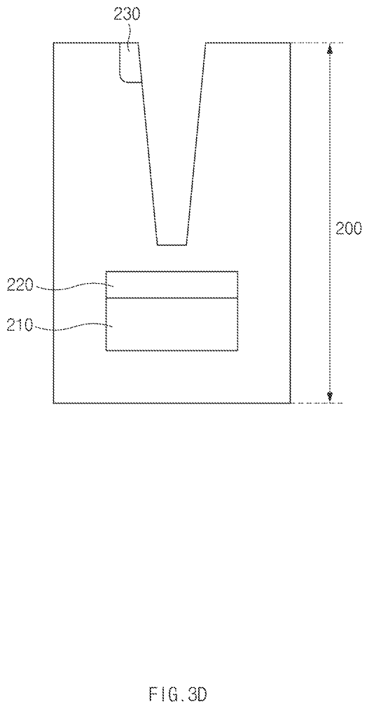

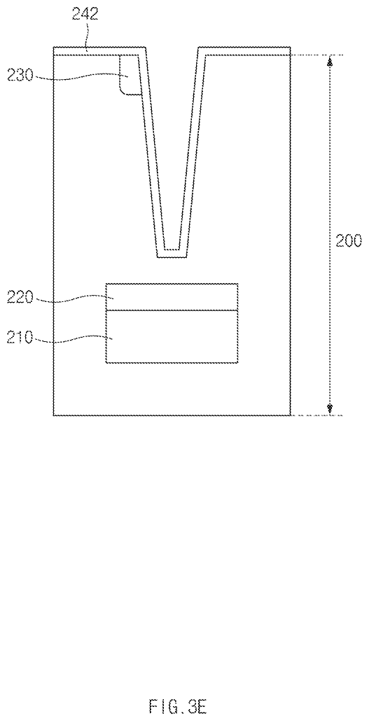

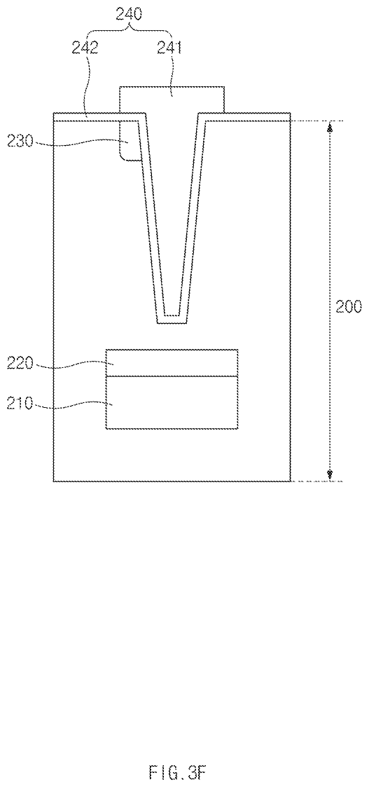

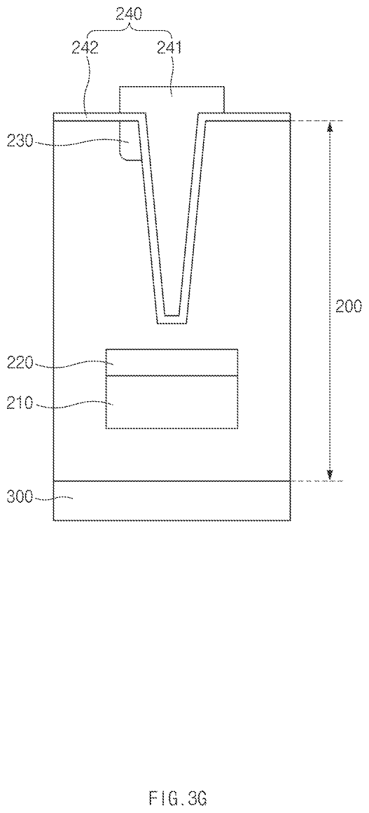

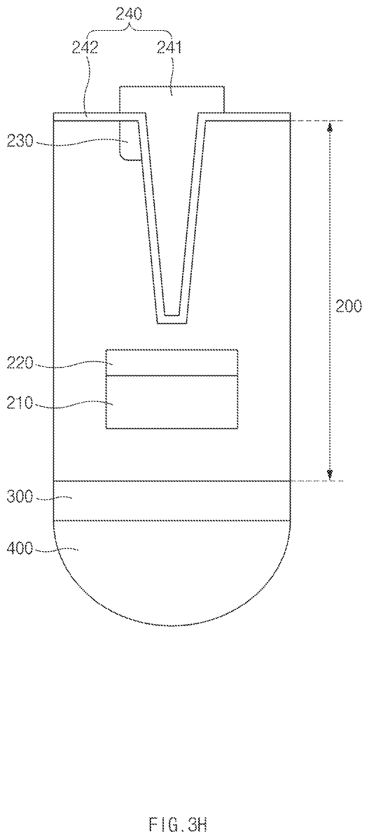

FIG. 2 is a cross-sectional view illustrating an example of a portion of an image sensing device that includes unit pixels PX1 and PX2 disposed in a pixel array 110 based on some implementations of the disclosed technology.

Referring to FIG. 2, each of the unit pixels PX1 and PX2 may include a plurality of devices disposed in a semiconductor substrate 200. The unit pixel PX1 may include an optical filter 300a and a microlens 400a, and the unit pixel PX2 may include an optical filter 300b and a microlens 400b.

For example, the semiconductor substrate 200 may include a silicon substrate doped with impurities or an epitaxial layer. Each unit pixel may include a transistor region in which a plurality of transistors is disposed.

Each of the optical filters 300a and 300b may selectively transmit incident light. Each of the optical filters 300a and 300b may selectively transmit incident light having a predetermined wavelength among a plurality of wavelengths of incident lights.

As the optical filters 300a and 300b selectively transmit incident light, photocharges corresponding to the incident light having penetrated the optical filters 300a and 300b may be generated in the photoelectric conversion regions 210a, 220a, 210b, and 220b.

Each of the microlenses 400a and 400b may converge incident light, and may transmit the converged light to be directed or guided to the semiconductor substrate 200.

The semiconductor substrate 200 may include first photoelectric conversion regions 210a and 210b, second photoelectric conversion regions 220a and 220b, floating diffusion regions 230a and 230b, and recess gates 240a and 240b.

Each of the first photoelectric conversion regions 210a and 210b may be disposed in the semiconductor substrate 200, and may be formed by vertically stacking a plurality of impurity regions having a first conductivity type (e.g., N-type).

In some implementations, electron-hole pairs corresponding to incident light may be generated inside the semiconductor substrate 200, and the first photoelectric conversion regions 210a and 210b may collect the electrons or holes. For example, the first photoelectric conversion regions 210a and 210b may include a photodiode, a phototransistor, a photogate, or a combination thereof.

The second photoelectric conversion regions 220a and 220b may be disposed inside the semiconductor substrate 200, and may be formed to be in contact with at least one surface of the first photoelectric conversion regions 210a and 210b. In some implementations, the second photoelectric conversion regions 220a and 220b may be formed to overlap at least a portion of the first photoelectric conversion regions 210a and 210b.

The second photoelectric conversion regions 220a and 220b may have a first conductivity type (e.g., N-type), and the second photoelectric conversion regions 220a and 220b may also collect electron-hole pairs corresponding to incident light in a similar way to the first photoelectric conversion regions 210a and 210b.

The second photoelectric conversion regions 220a and 220b may be disposed to be spaced apart from the recess gates 240a and 240b. As the second photoelectric conversion regions 220a and 220b are formed, a difference in distance between the photoelectric conversion regions (220a, 220b) and the recess gates (240a, 240b), which are caused due to the difference between depths of the recess gates 240a and 240b in the unit pixels PX1 and PX2, can be reduced.

The floating diffusion regions 230a and 230b may be formed adjacent to one surface of the semiconductor substrate 200, and may be spaced apart from the first photoelectric conversion regions 210a and 210b and the second photoelectric conversion regions 220a and 220b. In addition, the floating diffusion regions 230a and 230b may be formed to contact the recess gates 240a and 240b.

The floating diffusion region 230a may receive and store photocharges generated by the photoelectric conversion regions 210a and 220a. The floating diffusion region 230b may receive and store photocharges generated by the photoelectric conversion regions 210b and 220b. Photocharges may be transferred from the photoelectric conversion regions 210a and 220a to the floating diffusion region 230a according to a signal applied to the recess gate 240a, and photocharges may be transferred from the photoelectric conversion regions 210b and 220b to the floating diffusion region 230b according to a signal applied to the recess gate 240b.

For example, each of the recess gates 240a and 240b may be a transfer gate included in the transfer transistor, and a signal applied to the recess gates 240a and 240b may be a transfer signal. The floating diffusion regions 230a and 230b may have a first conductivity type (e.g., N-type).

Each of the recess gates 240a and 240b may be formed to extend from one surface of the semiconductor substrate 200 to the inside of the semiconductor substrate 200. The recess gate 240a may include a gate electrode 241a and a gate insulation layer 242a, and the recess gate 240b may include a gate electrode 241b and a gate insulation layer 242b. The gate electrode 241a may be electrically isolated from the devices formed in the semiconductor substrate 200 by the gate insulation layer 242a, and the gate electrode 241b may be electrically isolated from the devices formed in the semiconductor substrate 200 by the gate insulation layer 242b.

Each of the gate electrodes 241a and 241b may include a conductive material. For example, the conductive material may include metal and polysilicon. Each of the gate insulation layers 242a and 242b may include silicon oxide, silicon nitride, or a high-permittivity (high-K) material.

The gate insulation layers 242a and 242b may be formed to contact one surface of the semiconductor substrate 200, and may be formed to surround the gate electrodes 241a and 241b. A region where the recess gates 240a and 240b are formed in the semiconductor substrate 200 may be referred to as a recess region.

Due to various causes, for example, a process error, the depth at which the recess gates 240a and 240b are formed from one surface of the semiconductor substrate 200 may vary for each unit pixel.

For example, referring to FIG. 2, the depth (Da) of the recess gate 240a included in the first unit pixel PX1 may be greater than the depth (Db) of the recess gate 240b included in the second unit pixel PX2. The depth Da or Db of the recess gate 240a or 240b may refer to a distance from one surface of the semiconductor substrate 200 to a bottom surface of each recess gate 240a or 240b. As the depth Da of the recess gate 240a of the unit pixel PX1 and the depth Db of the recess gate 240b of the unit pixel PX2 are different from each other, the distance between the recess gate 240a and the first photoelectric conversion region 210a in the unit pixel PX1 and the distance between the recess gate 240b and the first photoelectric conversion region 210b in the unit pixel PX2 may also become different.

For example, when the second photoelectric conversion regions 220a and 220b are not formed in FIG. 2, the distance between the recess gate 240a and the first photoelectric conversion region 210a in the first unit pixel PX1 may be shorter than the distance between the recess gate 240b and the first photoelectric conversion region 210b in the second unit pixel PX2.

When the distance between the recess gate 240a and the first photoelectric conversion region 210a in the first unit pixel PX1 is shorter than the distance between the recess gate 240b and the first photoelectric conversion region 210b in the second unit pixel PX2, the first unit pixel PX1 may have a higher photocharge transfer efficiency than the second unit pixel PX2.

When a transfer signal having the same voltage level is applied to the recess gates 240a and 240b, the photocharge transfer efficiency may be determined based on the amount of photocharges transferred from the photoelectric conversion regions (210a, 210b) to the floating diffusion regions (230a, 230b) for each unit time.

When the transfer efficiency is low, photocharges generated in the photoelectric conversion regions 210a, 210b, 220a, and 220b may not be easily transferred to the floating diffusion regions 230a and 230b.

If there is a difference in the amount of photocharges transferred to the floating diffusion regions 230a and 230b in the first unit pixel PX1 and the second unit pixel PX2, a pixel signals generated for the first unit pixel PX1 and the second unit pixel PX2 may not correspond to the photocharges generated in the photoelectric conversion regions 210a and 210b and distortion may occur in image information. For example, since distances between recess gates of unit pixels and corresponding first photoelectric conversion regions of the unit pixels become different, the unit pixels have different transfer efficiencies from one another, which can cause a distortion in the image.

Various implementations of the disclosed technology provide a second photoelectric conversion region disposed in each unit pixel. In some implementations, the second photoelectric conversion region 220a is formed to contact the first photoelectric conversion region 210a in the first unit pixel PX1, and the second photoelectric conversion region 220b is formed to contact the first photoelectric conversion region 210b in the second unit pixel PX2, which results in an increase in transfer efficiency of the plurality of unit pixels PX1 and PX2.

As the second photoelectric conversion regions 220a and 220b are formed and configured to operate to generate and collect photocharges in response to incident light, the suggested implementations provide an extended photoelectric conversion region which includes both the first photoelectric conversion regions 210a and 210b and the second photoelectric conversion regions 220a and 220b. The extended photoelectric conversion region has a greater region extending toward the recess gates 240a and 240b as compared to the case without the second photoelectric conversion regions 220a and 220b.

Referring to FIG. 2, when the second photoelectric conversion regions 220a and 220b are formed, the distance D1 between the recess gate 240a and the extended photoelectric conversion region including the first photoelectric conversion region 210a and the second photoelectric conversion region 220a and the distance D2 between the recess gate 240b and the extended photoelectric conversion region including the first photoelectric conversion regions 210b and the second photoelectric conversion region 220b are shortened as compared to the case without the second photoelectric conversion regions 220a and 220b. Since the distance D1 and D2 are shortened, it is possible for photocharges to more easily move in each unit pixel from the photoelectric conversion regions to the floating diffusion regions.

The distance D1 between the second photoelectric conversion region 220a and the recess gate 240a may be determined depending on the depth (Da) of the recess gate 240a and the depth (La) at which the second photoelectric conversion region 220a is formed, and the distance D2 between the second photoelectric conversion region 220b and the recess gate 240b may be determined depending on the depth (Db) of the recess gate 240b and the depth (Lb) at which the second photoelectric conversion region 220b is formed.

In some implementations, the depth (La) at which the second photoelectric conversion region 220a is formed and the depth (Lb) at which the second photoelectric conversion region 220b is formed can be determined or adjusted such that each of the distance D1 between the second photoelectric conversion region 220a and the recess gate 240a in the first unit pixel PX1 and the distance D2 between the second photoelectric conversion region 220b and the recess gate 240b in the second unit pixel PX2 is shorter than a predetermined distance. In this case, the predetermined distance may serve as an experimental value, and may be a distance at which transfer efficiency of the unit pixels is equal to or greater than a threshold value.

In some other implementations, the depths La and Lb at which the second photoelectric conversion regions 220a and 220b are formed can be determined or adjusted such that the distance D1 between the second photoelectric conversion region 220a and the recess gate 240a in the first unit pixel PX1 and the distance D2 between the second photoelectric conversion region 220b and the recess gate 240b in the second unit pixel PX2 can be constantly maintained.

For example, when the depth (Da) of the recess gate 240a included in the first unit pixel PX1 is greater than the depth (Db) of the recess gate 240b included in the second unit pixel PX2, the depth (La) at which the second photoelectric conversion region 220a included in the first unit pixel PX1 is formed may be greater than the depth (Lb) at which the second photoelectric conversion region 220b included in the second unit pixel PX2 is formed.

In some implementations, the first photoelectric conversion regions 210a and 20b may be formed at the same depth from one surface of the semiconductor substrate 200. The second photoelectric conversion regions 220a and 220b may be formed to contact one surface of the first photoelectric conversion regions 210a and 210b, and the thickness (Ta) of the second photoelectric conversion region 220a included in the first unit pixel PX1 may be different from the thickness (Tb) of the second photoelectric conversion region 220b included in the second unit pixel PX2.

For example, the thickness (Ta) of the second photoelectric conversion region 220a included in the first unit pixel PX1 may be greater than the thickness (Tb) of the second photoelectric conversion region 220b included in the second unit pixel PX2.

The depth (La) at which the second photoelectric conversion region 220a is formed and the thickness (Ta) of the second photoelectric conversion region 220a, and the depth (Lb) at which the second photoelectric conversion region 220b is formed and the thickness (Tb) of the second photoelectric conversion region 220b may be adjusted or varied according to the concentration of implanted impurities, the strength of impurity implantation, and the number of processes of implanting impurities.

When the thickness of the second photoelectric conversion regions 220a formed in the first unit pixel PX1 is different from the thickness of the second photoelectric conversion region 220b formed in the second unit pixel PX2, the amount of photocharges generated in the first unit pixel PX1 and the amount of photocharges generated in the second unit pixel PX2 may also be different from each other. When there is a difference in the amount of photocharges between the first unit pixel PX1 and the second unit pixel PX2, an error may occur in the pixel signal.

While the distances and/or depths as shown in FIG. 2 are exaggerated for convenience of explanation, in the actual implementations, the area occupied by the second photoelectric conversion regions 220a and 220b is much smaller in size than the area occupied by the first photoelectric conversion regions 210a and 210b, so that an error of the pixel signal generated by a difference in thickness between the second photoelectric conversion regions 220a and 220b can be ignored.

FIGS. 3A to 3H are cross-sectional views illustrating a method for forming a unit pixel based on some implementations of the disclosed technology.

Referring to FIG. 3A, a first photoelectric conversion region 210 may be formed in the semiconductor substrate 200. The first photoelectric conversion region 210 may include a plurality of impurity regions having first conductivity types.

Referring to FIG. 3B, a recess region RR extending from one surface of the semiconductor substrate 200 toward the other surface of the semiconductor substrate 200 may be formed in the semiconductor substrate 200.

A first mask MASK1 may be formed on one surface of the semiconductor substrate 200. The first mask MASK1 may overlap the remaining regions other than the region where the recess region RR is formed.

A recess region RR may be formed by etching a region in which the first mask MASK1 is not formed through an etching process. The width and depth of the recess region RR may be determined according to the shape of the recess gate 240 to be formed in a subsequent process.

Referring to FIG. 3C, a second mask MASK2 may be formed in the recess region RR except for an open region (IO) in which the second photoelectric conversion region 220 is to be formed.

The second mask MASK2 may be formed to overlap a sidewall of the recess region RR and one surface of the semiconductor substrate 200.

The second mask MASK2 may prevent impurities from diffusing into the region in which the second mask MASK2 is formed.

In some implementations, the recess region RR except for the open region (IO) may be masked so that the second photoelectric conversion region is not formed at a sidewall of the recess region RR and the second photoelectric conversion region 220 can be formed at a bottom surface of the recess region RR.

The intensity of doping impurities, the number of times of introducing impurity doping, and the angle of introducing doping impurities can be adjusted or varied, so that the position at which the second photoelectric conversion region 220 is formed in the semiconductor substrate 200 and the shape of the second photoelectric conversion region 220 can also be adjusted or varied.

In some implementations, the shape of the second photoelectric conversion region 220 may be adjusted or varied according to the shape of the second mask MASK2 and the shape of the open region IO.

For example, the intensity of doping the impurities may increase so that the depth at which the second photoelectric conversion region 220 is formed from one surface of the semiconductor substrate 200 may also increase. When the first photoelectric conversion region 210 is located far from one surface of the semiconductor substrate 200, the second photoelectric conversion region 220 may be formed to contact one surface of the first photoelectric conversion region 210 by strongly doping impurities.

In some implementations, when the number of times of introducing doping impurities increases, the thickness of the second photoelectric conversion region 220 may become greater. As the impurity doping process is adjusted, the distance between the bottom surface of the recess region RR and the second photoelectric conversion region 220 can also be adjusted.

For all unit pixels included in the pixel array 110, if the distance between the bottom surface of the recess region RR and the second photoelectric conversion region 220 is determined to be shorter than a predetermined distance, charges can easily flow from the first photoelectric conversion region 210 to the floating diffusion region 230 within all unit pixels.

Alternatively, for all unit pixels included in the pixel array 110, the distance between the bottom surface of the recess region RR and the second photoelectric conversion region 220 may be set to a predetermined distance so that charge transfer characteristics can be adjusted to be constant in all pixels.

Referring to FIG. 3D, a floating diffusion region 230 may be formed in the semiconductor substrate 200. The floating diffusion region 230 may be doped with impurities having a first conductivity type. The floating diffusion region 230 may be formed by implanting impurities having the first conductivity type from one surface of the semiconductor substrate 200.

The length of a channel region formed between the floating diffusion region 230 and the second photoelectric conversion region 220 may vary depending on the distance between the floating diffusion region 230 and the second photoelectric conversion region 220. For example, the channel region may be formed when a voltage of an activation level is applied to the recess gate 240. Electrons generated in the first photoelectric conversion region 210 may be transferred to the floating diffusion region 230 after passing through the second photoelectric conversion region 220 and the channel region.

The recess gate 240 may be, for example, a transfer transistor gate included in the transfer transistor, and a signal applied to the recess gate 240 may be a transfer signal.

Referring to FIG. 3E, a gate insulation layer 242 may be formed to overlap the recess region RR and one surface of the semiconductor substrate 200.

For example, the gate insulation layer 242 may include silicon oxide, silicon nitride, or a high-permittivity (high-K) material.

In some other implementations, after the gate insulation layer 242 is formed, impurities having a first conductivity type may be implanted from the other surface of the semiconductor substrate 200.

Referring to FIG. 3F, a gate electrode 241 may be formed to contact an upper portion of the gate insulation layer 242. The gate electrode 241 may be disposed in the recess region RR in which the gate insulation layer 242 is formed, and may include a conductive material such as metal or polysilicon.

The recess gate 240 may include the gate electrode 241 and the gate insulation layer 242. Charges generated in the first photoelectric conversion region may be transferred to the floating diffusion region 230 according to a level of voltage applied to the recess gate 240.

Referring to FIG. 3G, an optical filter 300 may be formed to contact the other surface of the semiconductor substrate 200.

The optical filter 300 may selectively transmit incident light according to wavelengths of the incident light, and the incident light having penetrated the optical filter 300 may be converted into photocharges in the first photoelectric conversion region 210.

Referring to FIG. 3H, a microlens 400 may be formed to contact the optical filter 300. The microlens may allow incident light to be directed or guided to devices included in the unit pixel.

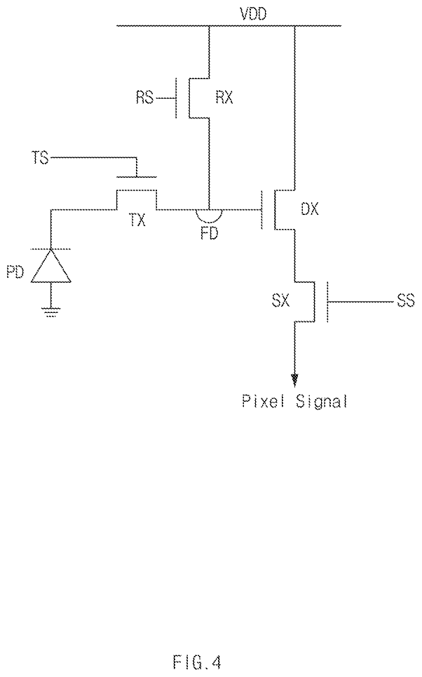

FIG. 4 is a circuit diagram illustrating an equivalent circuit of a unit pixel based on some implementations of the disclosed technology.

Referring to FIG. 4, a connection relationship among a photoelectric conversion region PD including first and second photoelectric conversion regions, a transfer transistor TX, a floating diffusion region FD, a reset transistor RX, a drive transistor DX, and a selection transistor SX is illustrated.

In addition, signals TS, RS, and SS respectively applied to the transistors TX, RX, and SX are shown in FIG. 4.

The recess gate 240 shown in FIGS. 2 to 3H may correspond to the transfer gate included in the transfer transistor TX. In addition, the first photoelectric conversion regions (210a, 210b, 210) and the second photoelectric conversion regions (220a, 220b, 220) shown in FIGS. 2 to 3H may correspond to the photoelectric conversion region PD, and the floating diffusion region 230 shown in FIGS. 2 to 3H may correspond to the floating diffusion region FD.

The reset transistor RX, the drive transistor DX, and the selection transistor SX′, which are not described in FIGS. 2 to 3H, may be disposed in the transistor region.

The transfer transistor TX may be disposed between the photoelectric conversion region PD and the floating diffusion region FD.

The transfer signal TS may be applied to the transfer transistor TX. Photocharges generated in the photoelectric conversion region PD may be transferred to the floating diffusion region FD according to a voltage level of the transfer signal TS. For example, the transfer signal TS may have an activation voltage level or a deactivation voltage level.

When the transfer signal TS has an activation voltage level, photocharges may be transferred from the photoelectric conversion region PD to the floating diffusion region FD.

The photocharges may be stored in the floating diffusion region FD.

The photocharges transferred to the floating diffusion region FD may be amplified by the drive transistor DX. The floating diffusion region FD may be connected to a gate of the drive transistor DX.

In addition, the floating diffusion region FD may be connected to one end of the reset transistor RX. The other end of the reset transistor RX may be connected to a pixel voltage VDD. The photoelectric conversion region PD and the floating diffusion region FD included in the unit pixel may be reset to the pixel voltage VDD according to a voltage level of a reset control signal RS applied to a gate of the reset transistor RX.

Since the photoelectric conversion region PD and the floating diffusion region FD are reset to the pixel voltage VDD, it may be possible to accurately measure the amount of photocharges generated in response to the incident light.

When the reset control signal RS has an activation voltage level, the transfer signal TS may have an activation voltage level. When each of the reset control signal RS and the transfer signal TS has an activation voltage level, the photoelectric conversion region PD and the floating diffusion region FD may be electrically connected to each other and may be reset to the pixel voltage VDD.

The selection transistor SX may selectively output the signal amplified by the drive transistor DX according to a selection control signal SS. A signal that is output from one end of the selection transistor SX may be referred to as a pixel signal.

The image sensing device 100 may generate image information based on a pixel signal that is output from each unit pixel.

As is apparent from the above description, the image sensing device based on some implementations of the disclosed technology can allow a second photoelectric conversion region to be disposed between a recess gate and a first photoelectric conversion region, so that transfer efficiency of photocharges generated in the first photoelectric conversion region can increase by the second photoelectric conversion region.

The embodiments of the disclosed technology may provide a variety of effects capable of being directly or indirectly recognized through the above-mentioned patent document.

Although a number of illustrative embodiments have been described, it should be understood that modifications and/or enhancements to the disclosed embodiments and other embodiments can be devised based on what is described and/or illustrated in this patent document.

What is claimed is:

1. A method for manufacturing an image sensing device, comprising:
forming a first photoelectric conversion region in a semiconductor substrate;
forming a recess region to extend in a direction from a surface of the semiconductor substrate toward an inside of the semiconductor substrate;
arranging a mask in a portion of the recess region;
forming a second photoelectric conversion region through the recess region; and
forming a recess gate in the recess region,
wherein a thickness of the second photoelectric conversion region is based on a depth of the recess gate that is measured from the surface of the semiconductor substrate to a bottom surface of the recess gate.

2. The method according to claim 1, wherein:
the second photoelectric conversion region is in contact with a surface of the first photoelectric conversion region.

3. The method according to claim 1, wherein the forming the recess gate includes:
forming a gate insulation layer in the recess gate; and
forming a gate electrode at an upper portion of the gate insulation layer.

4. The method according to claim 1, wherein:
the second photoelectric conversion region is doped with impurities having a conductivity type as same as that of the first photoelectric conversion region.

5. The method according to claim 1, wherein:
the second photoelectric conversion region is spaced apart from the recess gate.

6. The method according to claim 1, wherein the arranging the mask includes:
selectively masking the recess region except for a region in which the second photoelectric conversion region is to be formed.

7. The method according to claim 6, wherein the arranging the mask includes:
arranging the mask at a side surface of the recess region such that the mask is not disposed at a bottom surface of the recess region.

8. The method according to claim 7, wherein the forming the second photoelectric conversion region includes:
implanting impurities through the bottom surface of the recess region that is not masked.

9. An image sensing device, comprising:
a pixel array of a plurality of unit pixels configured to produce electric charge in response to incident light for imaging sensing,
wherein each of the plurality of unit pixels includes:
a first photoelectric conversion region disposed in a semiconductor substrate;
a recess gate extending in a direction from a surface of the semiconductor substrate to an inside of the semiconductor substrate; and
a second photoelectric conversion region disposed between the recess gate and the first photoelectric conversion region, and
wherein, in a first unit pixel and a second unit pixel that are included in the pixel array,
a depth of the recess gate included in the first unit pixel and measured from the surface of the semiconductor substrate to a bottom surface of the recess gate in the first unit pixel is greater than a depth of the recess gate included in the second unit pixel and measured from the surface of the semiconductor substrate to a bottom surface of the recess gate in the second unit pixel,
a thickness of a second photoelectric conversion region included in the first unit pixel is smaller than a thickness of a second photoelectric conversion region included in the second unit pixel.

10. The image sensing device according to claim 9, wherein:
in each of the plurality of unit pixels, the second photoelectric conversion region is in contact with the surface of the first photoelectric conversion region.

11. The image sensing device according to claim 9, wherein:
in each of the plurality of unit pixels, the second photoelectric conversion region is spaced apart from the recess gate.

12. The image sensing device according to claim 9, wherein:
in each of the plurality of unit pixels, the second photoelectric conversion region is doped with impurities having a conductivity type as same as that of the first photoelectric conversion region.

13. The image sensing device according to claim 9, wherein the recess gate further includes:
a gate electrode; and
a gate insulation layer disposed between the gate electrode and the second photoelectric conversion region.

14. The image sensing device according to claim 9, wherein a first distance between the bottom surface of the recess gate and the second photoelectric conversion region of the first unit pixel is equal to a second distance between the bottom surface of the recess gate and the second photoelectric conversion region of the second unit pixel.

15. The image sensing device according to claim 14, wherein:
a sum of the depth of the recess gate of the first unit pixel and the thickness of the second photoelectric conversion region of the first unit pixel is equal to a sum of the depth of the recess gate of the second unit pixel and the thickness of the second photoelectric conversion region of the second unit pixel.

16. The image sensing device according to claim 9, wherein the first photelectric conversion regions of the first unit pixel and the second unit pixel include a first surface closer to the surface of the semiconductor substrate and a second surface opposite to the first surface.

17. The image sensing device according to claim 9, wherein the thickness of the second photoelectric conversion region of each of the first unit pixel and the second unit pixel depends on a concentration of impurities, a strength of impurity implantation, or a number of times of impurity implantations.

18. The image sensing device according to claim 9, wherein the recess gate corresponds to a transfer transistor gate included in a transfer transistor.

19. The image sensing device according to claim 9, wherein the first unit pixel and the second unit pixel further comprises floating diffusion regions disposed to respectively contact the recess gates of the first unit pixel and the second unit pixel.

20. The image sensing device according to claim 19, wherein, in each of the first unit pixel and the second unit pixel, a length of a channel region formed between the floating diffusion region and the second photoelectric conversion region depend on a distance between the floating diffusion region and the second photoelectric conversion region.
